(19) United States
(12) Patent Application Publication
(10) Pub. No.: US 2025/0144669 A1
(43) Pub. Date: May 8, 2025

(54) VIBRATION REDUCTION IN ION IMPLANTERS USING EMBEDDED ACTUATOR FORCED ATTENUATION

(71) Applicant: Applied Materials, Inc., Santa Clara, CA (US)

(72) Inventors: Jordan B. TYE, Arlington, MA (US); Craig Richard CHANEY, Lanesville, MA (US); Jack Joseph LOPICCOLO, Gloucester, MA (US); James P. BUONODONO, Amesbury, MA (US)

(73) Assignee: Applied Materials, Inc., Santa Clara, CA (US)

(21) Appl. No.: 18/502,826

(22) Filed: Nov. 6, 2023

(51) Int. Cl. B06B 1/16; H01J 37/02; H01L 21/687

(52) U.S. Cl. CPC B06B 1/16; H01J 37/02; H01L 21/68707; B06B 2201/30; H01J 2237/0216

(57) ABSTRACT

A vibrating actuator adapted to be installed within a component of an ion implanter, the vibrating actuator including a housing defining an internal cavity, and a vibrating mechanism disposed within the internal cavity, the vibrating mechanism including an actuating element and a vibratory element coupled to the actuating element, wherein when an electrical signal is applied to the actuating element, the actuating element moves the vibratory element to vibrate the housing.

### FIELD OF THE DISCLOSURE

Embodiments of the present disclosure relate generally to the field of semiconductor device fabrication, and more particularly to devices and methods for reducing unwanted vibrations in ion implantation systems.

### BACKGROUND OF THE DISCLOSURE

Ion implantation systems (“ion implanters”) are used in the manufacture of semiconductor devices to introduce dopants or impurities into semiconductor wafers via ion bombardment. This process requires extreme precision, control, and stability, both for handling a semiconductor wafer and for focusing and directing an ion beam at a wafer to achieve effective implantation. Vibration, even in minute magnitudes, can detrimentally affect ion implanters for a host of reasons.

For example, vibrations can disrupt the highly sensitive alignment and positioning of an ion beam. Ion implantation requires accurate focusing of the ion beam onto a wafer surface, with sub-micron precision. Even slight vibrations can cause an ion beam to deviate from its intended path, leading to inaccuracies in dopant placement and concentration. This directly affects the performance and reliability of manufactured semiconductor devices, leading to yield loss and compromised functionality.

Furthermore, vibrations can adversely affect the uniformity of ion distribution. During ion implantation, uniform dopant distribution across an entire wafer is crucial to ensure consistent device characteristics. Vibrations can cause localized fluctuations in ion dose delivery, resulting in uneven dopant profiles and compromised device performance. This lack of uniformity can lead to increased variability in device parameters, reducing product quality and reliability.

Still further, vibrations can detrimentally affect the handling of wafers in an ion implanter. For example, vibrations in an end effector of a wafer handling robot can cause wafer walk out and can also result in backside damage to a wafer. Wafer handling speeds are typically reduced to account for these considerations, resulting in reduced wafer throughput.

Vibrations can be caused by numerous sources both internal and external to an ion implanter. For example, pumps, chillers, controllers, and other mechanisms within an ion implanter can produce vibrations. Building facilities and machinery adjacent an ion implanter can also produce vibrations. Ideally, all such vibrations would be accounted for and mitigated within the components of an ion implanter to ensure precision and stability with regard to both wafer handling and beam optics.

With respect to these and other considerations, the present improvements may be useful.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In accordance with an embodiment of the present disclosure, a vibrating actuator adapted to be installed within a component of an ion implanter may include a housing defining an internal cavity and a vibrating mechanism disposed within the internal cavity. The vibrating mechanism may include an actuating element and a vibratory element coupled to the actuating element, wherein, when an electrical signal is applied to the actuating element, the actuating element moves the vibratory element to vibrate the housing.

In accordance with another embodiment of the present disclosure, a system for reducing unwanted vibration in a component of an ion implantation system may include a vibrating actuator sealed within the component, the vibrating actuator including a housing defining an internal cavity and a vibrating mechanism disposed within the internal cavity. The vibrating mechanism may include an actuating element, and a vibratory element coupled to the actuating element, wherein, when an electrical signal is applied to the actuating element, the actuating element moves the vibratory element to vibrate the housing and the component.

In accordance with another embodiment of the present disclosure, a system for reducing unwanted vibration in a component of an ion implantation system may include a vibrating actuator sealed within the component, the vibrating actuator including a housing defining an internal cavity, and a vibrating mechanism disposed within the internal cavity, the vibrating mechanism adapted to vibrate in response to an external vibration to interfere with the external vibration.

In accordance with another embodiment of the present disclosure, a method of embedding a vibrating actuator within a component of an ion implantation system may include starting an additive manufacturing process to build the component, including forming an internal cavity within the component, pausing the additive manufacturing process while the internal cavity is still open, installing the vibrating actuator within the cavity, and restarting the additive manufacturing process to cap the internal cavity and seal the vibrating actuator within the internal cavity.

### BRIEF DESCRIPTION OF THE DRAWINGS

By way of example, various embodiments of the disclosed techniques will now be described, with reference to the accompanying drawings, wherein:

FIG. 1A is a perspective view illustrating a vibrating actuator in accordance with the present disclosure;

FIGS. 1B-1G are a series of cross-sectional views illustrating several varieties of vibrating actuators in accordance with embodiments of the present disclosure;

FIG. 2 is a flow diagram illustrating a manufacturing method in accordance with the present disclosure;

FIGS. 3A-3E are a series of perspective views illustrating various ion implantation system components with embedded vibrating actuators and other devices in accordance with embodiments of the present disclosure.

### DETAILED DESCRIPTION

The present embodiments will now be described more fully hereinafter with reference to the accompanying drawings, wherein some embodiments are shown. The subject matter of the present disclosure may be embodied in many different forms and is not to be construed as limited to the embodiments set forth herein. These embodiments are provided so this disclosure will be thorough and complete, and will convey certain exemplary aspects of the subject matter to those skilled in the art. In the drawings, like numbers refer to like elements throughout.

Embodiments of the present disclosure are directed to apparatuses and methods for reducing vibrations in various components of ion implantation systems (“ion implanters”) by embedding vibrating actuators within such components. The vibrating actuators may be configured to vibrate at frequencies and amplitudes that interfere with unwanted vibrations produced by other components or structures internal or external to an ion implanter to cancel or mitigate such vibrations. In various embodiments, the vibrating actuators may be embedded within various components of an ion implanter using additive manufacturing techniques as further described below.

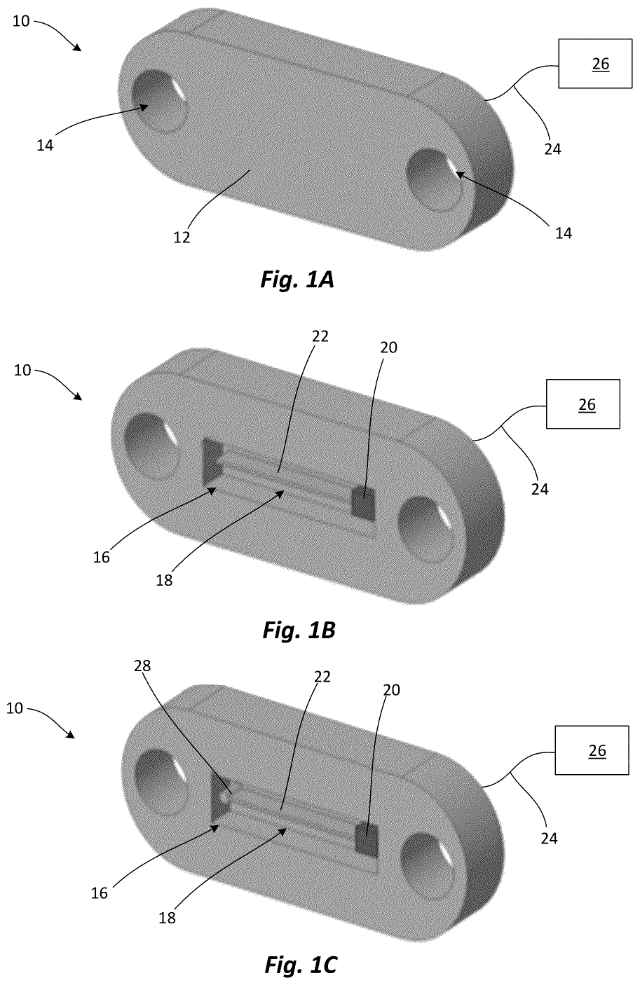

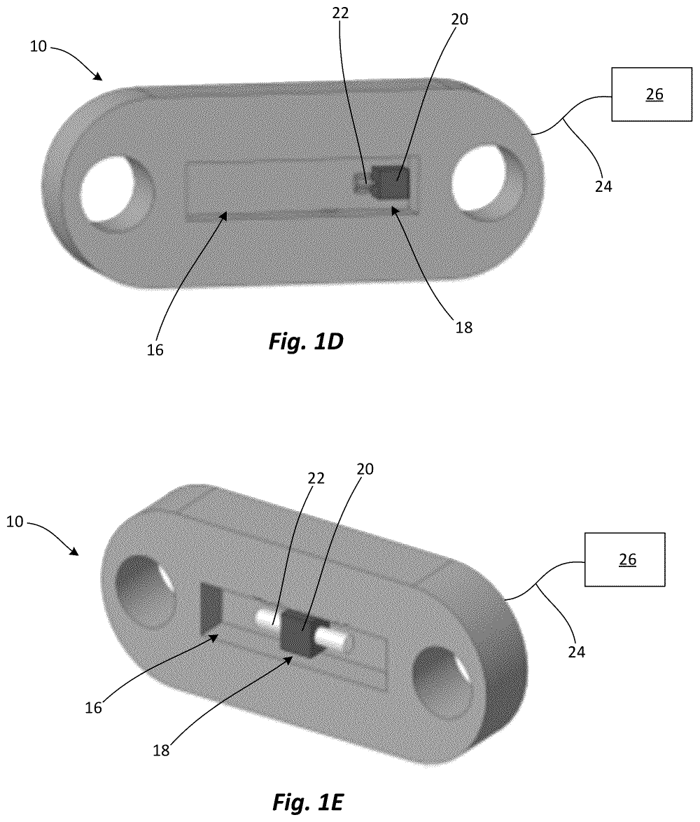

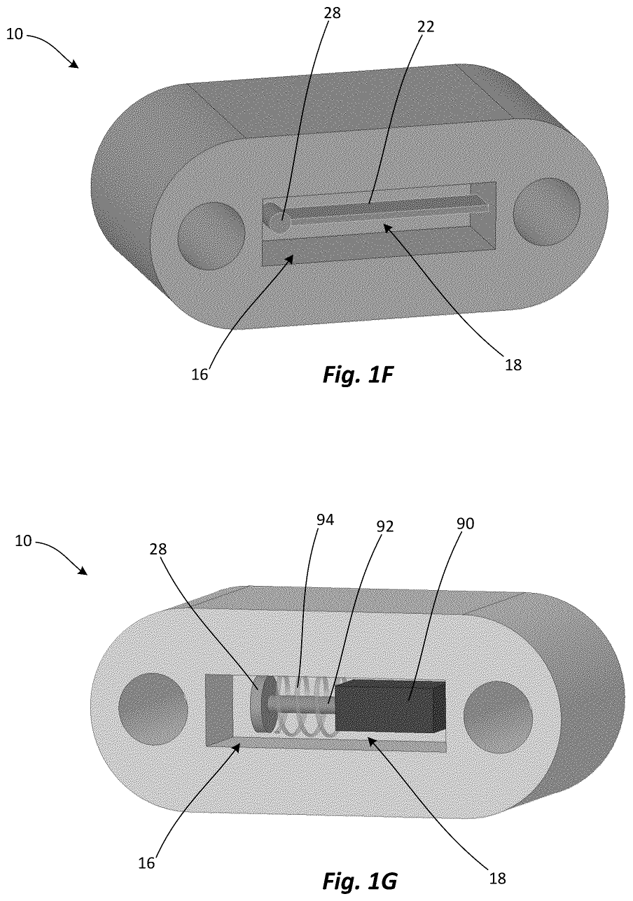

Referring to FIGS. 1A and 1B, a perspective view and a cross-sectional view illustrating a vibrating actuator 10 (hereinafter “the actuator 10”) in accordance with an embodiment of the present disclosure are shown, respectively. For the sake of convenience and clarity, terms such as “top,” “bottom,” “upper,” “lower,” “front,” “rear,” “lateral,” and “longitudinal,” may be used herein to describe the relative position and orientation of various components and features of the actuator 10, all with respect to the geometry and orientation of the actuator 10 as it appears in the views shown in FIGS. 1A and 1B. Said terminology is not intended to be limiting and includes the words specifically mentioned, derivatives thereof, and words of similar import.

The actuator 10 may include a housing 12 having the shape of a cuboid with rounded longitudinal ends as shown. This shape is not intended to be limiting. Alternative embodiments are contemplated wherein the housing 12 is provided with a variety of other exterior shapes (e.g., cuboid, spherical, conical, cylindrical, irregular, etc.). The housing 12 may include one or more mounting holes 14 formed therethrough for receiving mechanical fasteners (not shown) to facilitate installation of the actuator 10 within a component of an ion implanter as further described below. Alternative embodiments of the housing 12 are contemplated wherein the mounting holes 14 are omitted, such as if the actuator 10 is to be installed or mounted via welding, adhesives, etc. The housing 12 may be formed of any of a variety of different materials, including, and not limited to, various metals (e.g., aluminum, stainless steel, etc.), plastics, and composites.

Referring to FIG. 1B, the housing 12 may have an internal cavity 16 with a vibrating mechanism 18 disposed therein. The vibrating mechanism 18 may include an actuating element 20 mounted to a wall (e.g., a rear wall or a sidewall) of the internal cavity 16, and a vibratory element 22 coupled to the actuating element 20 and extending longitudinally through the internal cavity 16. In various embodiments, the actuating element 20 may be a piezoelectric element (i.e., a transducer that converts electrical energy into a mechanical displacement), and the vibratory element 22 may be an elongated strip of flexible material. In various embodiments, the vibratory element 22 may be formed of a metal such as stainless steel or aluminum, or a polymer with or without reinforcements. The present disclosure is not limited in this regard.

When an electrical signal is applied to the actuating element 20 (e.g., via a wire 24 connected to an electrical power source 26 external to the actuator 10), the actuating element 20 may oscillate the vibratory element 22, thus producing a vibration in the housing 12 and in any components connected to the actuator 10 as further described below. The frequency and amplitude of the oscillation can be tuned by adjusting the frequency and amplitude of the electrical input provided to the actuating element 20. Of course, the specific characteristics of the actuating element 20, as well as the size, material, and cross-sectional shape of the vibratory element 22, will also influence the frequency and amplitude of vibration. The vibratory element 22 is shown as having a rectangular cross-sectional shape. This is not intended to be limiting, and alternative embodiments are contemplated wherein the vibratory element 22 is provided with a variety of other cross-sectional shapes (e.g., circular, rectangular, triangular, oval, irregular, etc.).

Referring to FIG. 1C, a cross-sectional view illustrating an alternative embodiment of the actuator 10 is shown. This embodiment is identical to the embodiment shown in FIG. 1B, except that the vibratory element 22 of the vibrating mechanism 18 terminates in a weight 28 at a free end thereof (i.e., at a longitudinal end of the vibratory element 22 opposite the actuating element 20). In various embodiments, the weight 28 may be a bulbous mass formed as a contiguous extension of the material of the vibratory element 22 (i.e., the vibratory element 22 and the weight 28 may be formed from a single, contiguous piece of material). Alternatively, the weight 28 may be formed separately from the vibratory element 22 (i.e., the vibratory element 22 and the weight 28 may be formed from separate pieces of material, and optionally different types of material) and may be affixed to the free end of the vibratory element 22 by mechanical fasteners or adhesives. The present disclosure is not limited in this regard. The weight 28 may serve to increase the amount of force applied to the vibratory element 22 to change the natural frequency of the vibratory element 22 and achieve a desired vibratory frequency in the actuator 10. For example, a heavier weight will result in a lower natural frequency.

Referring to FIG. 1D, a cross-sectional view illustrating another alternative embodiment of the actuator 10 is shown, wherein the actuating element 20 may be a rotary actuator (e.g., a motor), and the vibratory element 22 may be an offset weight coupled to, or formed as a contiguous part of, a shaft of the actuating element 20. The term “offset weight” shall be defined herein to mean a weight having a mass that is radially distributed asymmetrically relative to an axis of the shaft of the actuating element 20.

When an electrical signal is applied to the actuating element 20 (e.g., via the wire 24 connected to the electrical power source 26), the actuating element 20 may spin the vibratory element 22 (i.e., the offset weight). As the vibratory element 22 spins, the rotating, radially unbalanced load will cause rapid, radial deflection of the shaft of the actuating element 20, thus producing a vibration in the housing 12 and in any components connected to the actuator 10 as further described below. The frequency and amplitude of the vibration can be tuned by adjusting the frequency of the electrical input provided to the actuating element 20 to vary the speed of rotation. Of course, the specific characteristics of the actuating element 20, as well as the size, shape, and weight of the vibratory element 22, will also influence the frequency and amplitude of vibration.

Referring to FIG. 1E, a cross-sectional view illustrating another alternative embodiment of the actuator 10 is shown, wherein the actuating element 20 may be a linear actuator (e.g., a motor), and the vibratory element 22 may be a cylindrical weight extending through the linear actuator.

When an electrical signal is applied to the actuating element 20 (e.g., via the wire 24 connected to the electrical power source 26), the actuating element 20 may drive the vibratory element 22 longitudinally back and forth in a reciprocating manner (as indicated by the arrow 30). The rapid reciprocation of the vibratory element 22 (i.e., the cylindrical weight) may produce a vibration in the housing 12 and in any components connected to the actuator 10 as further described below. The frequency and amplitude of the vibration can be tuned by adjusting the frequency and amplitude of the electrical input provided to the actuating element 20 to vary the speed of reciprocation. Of course, the specific characteristics of the actuating element 20, as well as the size, shape, and weight of the vibratory element 22, will also influence the frequency and amplitude of vibration. The vibratory element 22 is shown as having a circular cross-sectional shape. This is not intended to be limiting, and alternative embodiments are contemplated wherein the vibratory element 22 is provided with a variety of other cross-sectional shapes (e.g., rectangular, triangular, oval, irregular, etc.).

Referring to FIG. 1F, a cross-sectional view illustrating another alternative embodiment of the actuator 10 is shown, wherein an actuating element is entirely omitted. Instead, the vibrating mechanism 18 may include a vibratory element 22 coupled to a wall of the internal cavity 16 and extending longitudinally through the internal cavity 16. In various embodiments, the vibratory element 22 may be an elongated strip of flexible material (e.g., a metal such as stainless steel or aluminum, or a polymer with or without reinforcements). The present disclosure is not limited in this regard. The vibratory element 22 may terminate in a weight 28 at a free end thereof (i.e., at a longitudinal end of the vibratory element 22 opposite the end affixed to the wall of the internal cavity 16). In various embodiments, the weight 28 may be a bulbous mass formed as a contiguous extension of the material of the vibratory element 22 (i.e., the vibratory element 22 and the weight 28 may be formed from a single, contiguous piece of material). Alternatively, the weight 28 may be formed separately from the vibratory element 22 (i.e., the vibratory element 22 and the weight 28 may be formed from separate pieces of material, and optionally different types of material) and may be affixed to the free end of the vibratory element 22 by mechanical fasteners or adhesives.

When the actuator 10 is vibrated by an external force, the vibrating mechanism 18 may oscillate and may produce a vibration. By properly selecting the characteristics of the vibratory element 22 and the weight 28 (e.g., material, length, weight, stiffness, shape, etc.), the vibrating mechanism 18 can be configured to vibrate with a frequency and an amplitude adapted to constructively or destructively interfere with the external vibration.

Referring to FIG. 1G, a cross-sectional view illustrating another alternative embodiment of the actuator 10 is shown, wherein an actuating element is entirely omitted. Instead, the vibratory element 22 of the vibrating mechanism 18 may include a damper 90 and an axially movable rod 92 coupled to the damper 90. The rod 92 may terminate in a weight 28 at a free end thereof (i.e., at a longitudinal end of the rod 92 opposite the damper 90). In various embodiments, the weight 28 may be a bulbous mass formed as a contiguous extension of the material of the rod 92 (i.e., the rod 92 and the weight 28 may be formed from a single, contiguous piece of material). Alternatively, the weight 28 may be formed separately from the rod 92 (i.e., the rod 92 and the weight 28 may be formed from separate pieces of material, and optionally different types of material) and may be affixed to the free end of the rod 92 by mechanical fasteners or adhesives. A coil spring 94 may surround the rod 92 and may be axially held between the weight 28 and the damper 90.

When the actuator 10 is vibrated by an external force, the rod 92 and the weight 28 may oscillate (e.g., axially reciprocate relative to the damper 90), with the damper 90 and the coil spring 94 damping the oscillation. The vibrating mechanism 18 may thus produce a vibration of a given frequency and amplitude. By properly selecting the characteristics of the weight 28, the coil spring 94, and the damper 90 (e.g., weight, spring rate, damping rate, etc.), the vibrating mechanism 18 can be configured to vibrate with a frequency and an amplitude adapted to constructively or destructively interfere with the external vibration.

The embodiments of the actuator 10 described above, including the various actuating elements 20 and vibratory elements 22 employed in such embodiments, are provided by way of example only and are not intended to be limiting. Those of skill in the art will appreciate that numerous other actuators and controllable vibrating mechanisms may be similarly implemented in the apparatuses, systems, and methods described below.

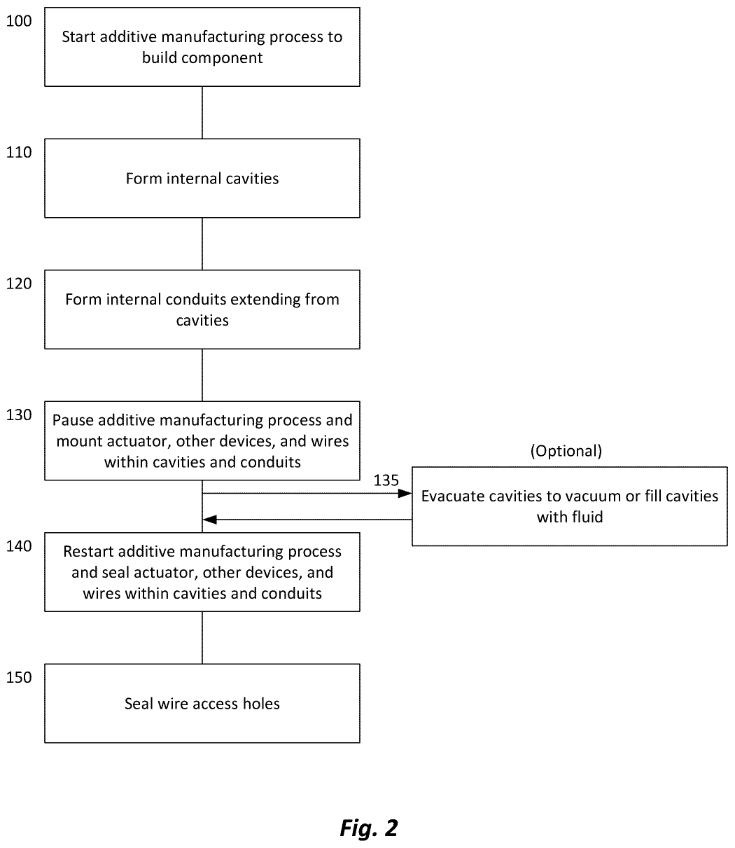

The actuator 10 of the present disclosure may be embedded within various components commonly found in ion implantation systems and may be operated to nullify or minimize unwanted vibrations in such components through constructive or destructive interference. For example, the actuator 10 may be operated (actively, as in the embodiments shown in FIGS. 1B-1E, or passively, as in the embodiments shown in FIGS. 1F and 1G) to produce a vibration that “cancels out” the unwanted vibration. The embodiments of the present disclosure leverage modern additive manufacturing processes (e.g., 3D printing) to facilitate internal installation (i.e., embedding) of the actuator 10 within ion implantation system components. For example, in block 100 of the method set forth in the flow diagram of FIG. 2, an additive manufacturing process may be started to build a component of an ion implantation system (hereinafter “the component”). During this process, at block 110 of the method, one or more internal pockets or cavities may be formed in the component. The cavities may be of any suitable sizes and shapes for accommodating the actuator 10 and various other devices, such a vibration sensor or accelerometer (described in greater detail below). Additionally, at block 120 of the method, the additive manufacturing process may include forming internal channels or conduits in the component to accommodate power and/or control wires (e.g., the wire 24 described above) for supplying electrical power and control signals to the actuator 10 and other devices disposed within the one or more cavities. Such channels may extend from the one or more cavities to an exterior surface of the component, for example. At block 130 of the method, while the one or more cavities and conduits are still open (e.g., when the additive manufacturing process reaches a top or extent of the one or more cavities and conduit but before the one or more cavities and conduits are sealed), the additive manufacturing process may be paused, and the actuator 10, other devices, and any wires may be mounted within the one or more cavities and in the conduits, respectively. At block 140 of the method, after the actuator 10, other devices, and any wires have been installed, the build process may be restarted, thus capping the one or more cavities and the conduits and sealing the actuator 10, other devices, and wires within the component. Optionally, at block 135 of the method, prior to sealing, the one or more cavities may be evacuated to vacuum to minimize air resistance for the vibratory element 22 of the actuator 10, for example. Alternatively, the one or more cavities may be filled with a liquid or gas to help dissipate heat from the one or more cavities and thus improve the thermal performance of the actuating element 20, and/or to modify the frequency of vibration of the vibratory element 22. Such liquids and gases may include, and are not limited to, nitrogen, helium, air, deionized water, oil, and other high thermal conductivity fluids. At block 150 of the method, after the additive manufacturing process is complete, any wire access holes in the component may be sealed at the exterior surface of the component.

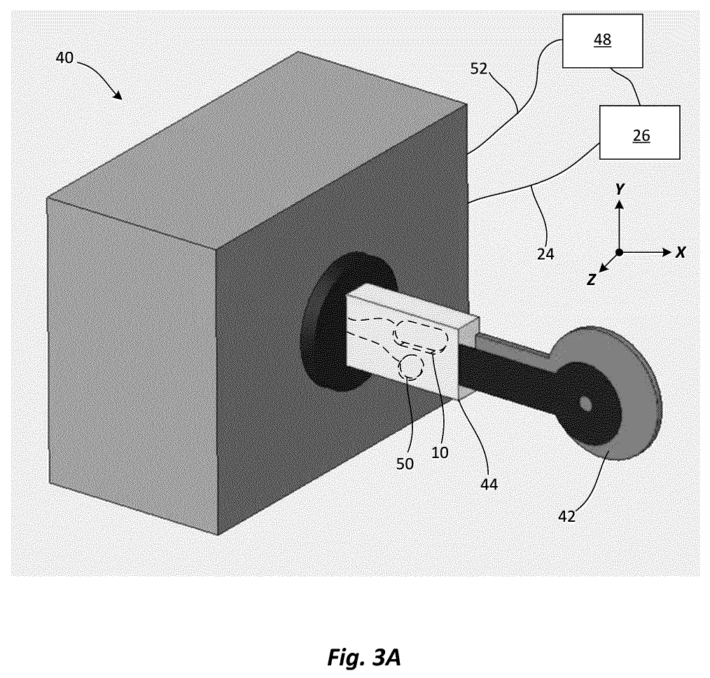

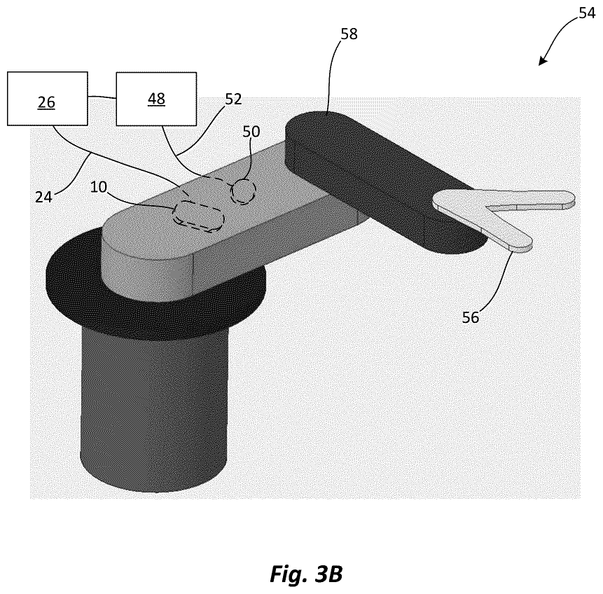

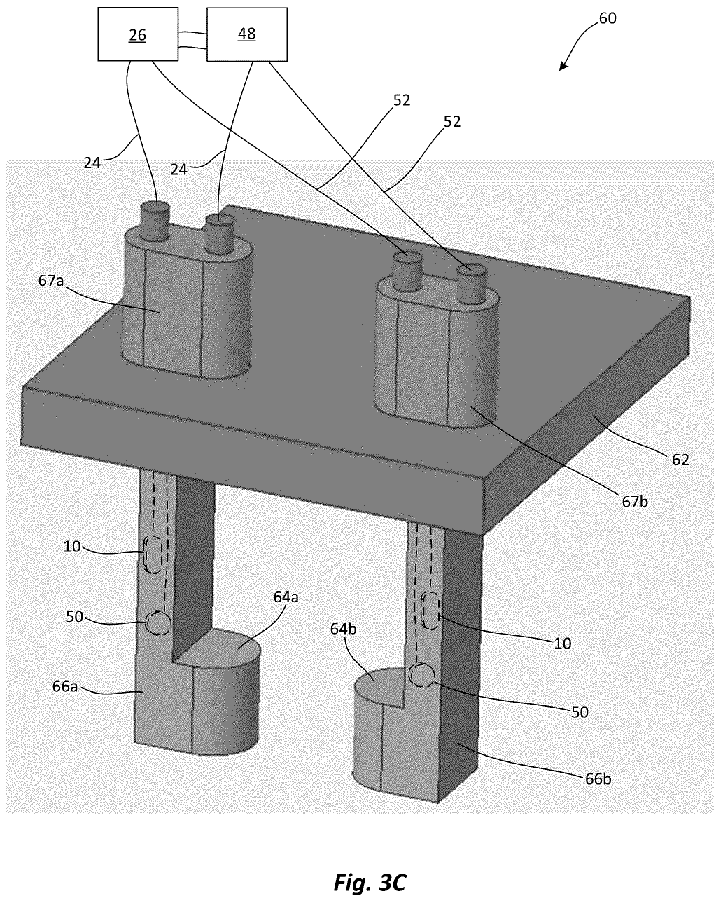

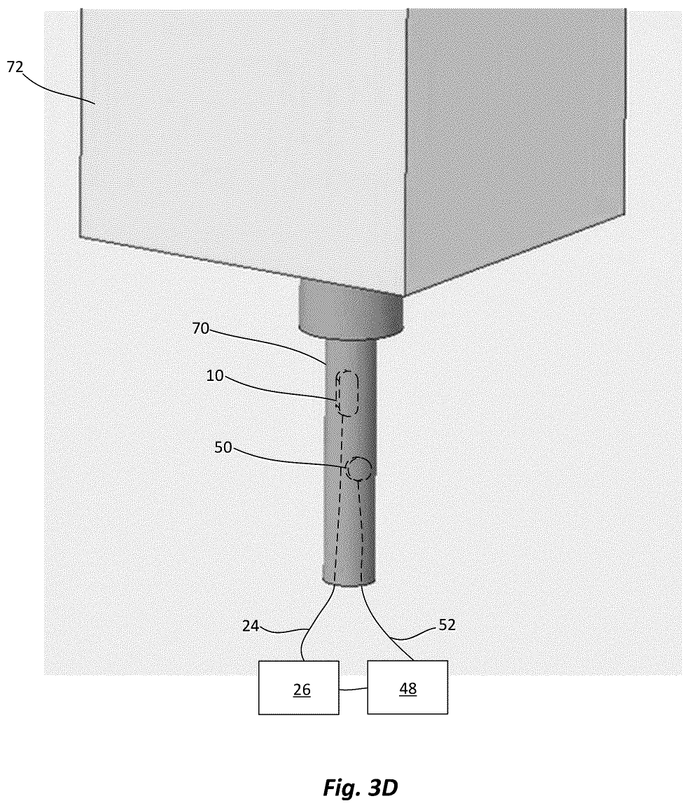

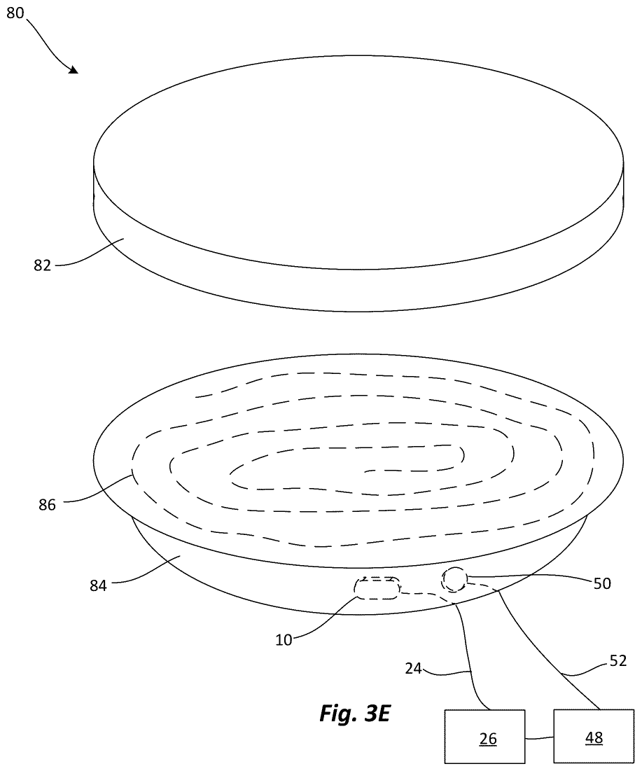

Referring to FIGS. 3A-3E, several examples of ion implantation system components are shown within which the actuator 10 of the present disclosure may be embedded. These examples are not intended to be limiting, and those of skill in the art will appreciate that the actuator 10 may be similarly implemented within various other ion implantation system components without departing from the scope of the present disclosure.

Referring to FIG. 3A, a perspective view depicting an ion beam manipulator 40 (hereinafter “the manipulator 40”) as a first example of an ion implantation system component is shown. The manipulator 40 may include an electrostatic lens 42 mounted on a movable arm 44. The arm 44 may facilitate translation of the arm 44 in directions parallel to the X, Y, and Z axes of the illustrated Cartesian coordinate system. The electrostatic lens 42 may thus be used to controllably steer and focus an ion beam projected therethrough.

The actuator 10 of the present disclosure, including any power wires 24 necessary for the operation thereof, may be embedded within various portions of the arm 44 using the additive manufacturing method described above and shown in FIG. 2. The power wire 24 may extend out of the arm 44 (and out of the ion implantation system of which the manipulator 40 is a part of) to an electrical power source 26, and the electrical power source 26 may be coupled to a controller 48 (e.g., a proportional-integral-derivative controller). Installed thusly, the actuator 10 may be operated to vibrate at a predetermined frequency and amplitude to constructively or destructively interfere with an unwanted vibration in the manipulator 40 to nullify or minimize the unwanted vibration, thus improving stability of the electrostatic lens 42 and ensuring proper steering and focusing of an ion beam projected therethrough. The predetermined frequency and amplitude may be dictated by the characteristics of the actuator 10 (e.g., the type of actuating element 20 and vibratory element 22 implemented in the actuator 10), and/or by the electrical signal supplied to the actuator 10 at the direction of the controller 48. For example, the controller 48 may modulate the frequency and amplitude of the electrical signal supplied by the electrical power source 26 to vibrate the actuator at the predetermined frequency and amplitude.

In various embodiments, a vibration sensor 50 (e.g., an accelerometer) may also be embedded in the arm 44 using the additive manufacturing method described above and shown in FIG. 2. The vibration sensor 50 may measure vibration in the arm 44 and may transmit a signal communicating the measured vibration to the controller 48 via an output wire 52. Based on the signal received from the vibration sensor 50, the controller 48 may adjust the frequency of the electrical signal supplied by the electrical power source 26 to tune the frequency and amplitude of vibration produced by the actuator 10 until the vibration sensor 50 measures no vibration or measures a vibration below a predetermined threshold. Thus, the vibration sensor 50 may be used to provide a closed loop feedback system for dynamically adjusting the vibration of the actuator 10 to counteract unwanted vibrations in the arm 44 that may change over time.

Referring to FIG. 3B, a perspective view depicting a transfer robot 54 (hereinafter “the robot 54”) as a second example of an ion implantation system component is shown. The robot 54 may include an end effector 56 mounted on a pick arm 58. During operation, the robot 54 may be used to move a semiconductor wafer (not shown) between various chambers, stations, and/or load locks of an ion implantation system, for example, with the semiconductor wafer being supported on a top surface of the end effector 56.

The actuator 10 of the present disclosure, including any power wires 24 necessary for the operation thereof, may be embedded within various portions of the pick arm 58 or the end effector 56 using the additive manufacturing method described above and shown in FIG. 2, and the actuator 10 may be operated to vibrate at a predetermined frequency and amplitude to interfere (destructively or constructively) with an unwanted vibration in the pick arm 58 or end effector 56 to nullify or minimize the unwanted vibration in the same manner as described above with respect to the arm 44 of the manipulator 40. Thus, the stability of the pick arm 58 and the end effector 56 may be improved to mitigate unwanted movement of a semiconductor wafer on the end effector 56 (so-called “wafer walk out”) and to mitigate backside damage to a wafer supported on the end effector 56.

Additionally, in various embodiments, a vibration sensor 50 (e.g., an accelerometer) may also be embedded in the pick arm 58 using the additive manufacturing method described above and shown in FIG. 2, and the vibration sensor 50 may be coupled to a controller 48 by an output wire 52. The vibration sensor 50 may be used to provide a closed loop feedback system (via the controller 48 and the electrical power source 26) for dynamically adjusting the vibration of the actuator 10 to counteract unwanted vibrations in the pick arm 58 in same manner as described above with respect to the arm 44 of the manipulator 40.

Referring to FIG. 3C, a perspective view depicting an electrostatic scanner (hereinafter “the scanner 60”) as a third example of an ion implantation system component is shown. The scanner 60 may include a mounting plate 62 for suspending the scanner 60 in a chamber downstream from an ion beam source, first and second scanning electrodes 64a, 64b suspended from the mounting plate 62 by respective first and second brackets 66a, 66b, an electrostatic lens 68 suspended from the mounting plate adjacent the first and second scanning electrodes 64a, 64b, and electrical passthroughs 67a, 67b, 67c extending through the mounting plate 62 for facilitating routing of electrical power lines (not shown) to the first and second scanning electrodes 64a, 64b and the electrostatic lens 68, respectively. During operation, the first and second scanning electrodes 64a, 64b and the electrostatic lens 68 may be selectively energized to scan an ion beam projected therethrough using electrostatic forces.

The actuator 10 of the present disclosure, including a power wires 24 necessary for the operation thereof, may be embedded within both of the first and second brackets 66a, 66b using the additive manufacturing method described above and shown in FIG. 2, and the actuators 10 may be operated to vibrate at predetermined frequencies and amplitudes to destructively interfere with unwanted vibrations in the first and second brackets 66a, 66b to nullify or minimize the unwanted vibrations in the same manner as described above with respect to the arm 44 of the manipulator 40. Thus, the stability of the first and second brackets 66a, 66b and the respective first and second scanning electrodes 64a, 64b may be improved, ensuring proper scanning of an ion beam projected therethrough.

Additionally, in various embodiments, vibration sensors 50 (e.g., accelerometers) may also be embedded in both of the first and second brackets 66a, 66b using the additive manufacturing method described above and shown in FIG. 2, and the vibration sensors 50 may be coupled to a controller 48 by output wires 52. The vibration sensor 50 may be used to provide a closed loop feedback system (via the controller 48 and the electrical power source 26) for dynamically adjusting the vibrations of the actuators 10 to counteract unwanted vibrations in the first and second brackets 66a, 66b in same manner as described above with respect to the arm 44 of the manipulator 40.

Referring to FIG. 3D, a perspective view depicting a scan shaft 70 as a third example of an ion implantation system component is shown. The scan shaft 70 may extend through a floor 72 of a process chamber (not within view) and may support a platen therein. During operation, the scan shaft 70 may be axially extended and retracted to raise and lower the platen, and a semiconductor wafer disposed thereon, within the process chamber. The scan shaft 70 may also be rotated about its axis to rotate the platen and the semiconductor wafer within the process chamber.

The actuator 10 of the present disclosure, including any power wires 24 necessary for the operation thereof, may be embedded within the scan shaft 70 using the additive manufacturing method described above and shown in FIG. 2, and the actuator 10 may be operated to vibrate at a predetermined frequency and amplitude to destructively interfere with an unwanted vibration in the scan shaft 70 to nullify or minimize the unwanted vibration in the same manner as described above with respect to the arm 44 of the manipulator 40. Thus, the stability of the scan shaft 70 and the platen may be improved to mitigate unwanted movement of, and backside damage to, a semiconductor wafer disposed on the platen.

Additionally, in various embodiments, a vibration sensor 50 (e.g., an accelerometer) may also be embedded in the scan shaft 70 using the additive manufacturing method described above and shown in FIG. 2, and the vibration sensor 50 may be coupled to a controller 48 by an output wire 52. The vibration sensor 50 may be used to provide a closed loop feedback system (via the controller 48 and the electrical power source 26) for dynamically adjusting the vibration of the actuator 10 to counteract unwanted vibrations in the scan shaft 70 in same manner as described above with respect to the arm 44 of the manipulator 40.

Referring to FIG. 3E, an exploded view depicting a platen assembly 80 as a third example of an ion implantation system component is shown. The platen assembly 80 may include a platen 82 and a cooling plate 84. When assembled, the platen 82 may sit directly atop the cooling plate 84. During operation, a cooling fluid may be circulated through an internal channel 86 within the cooling plate 84 to cool the cooling plate 84, the platen 82, and a semiconductor wafer (not shown) disposed on the platen 82.

The actuator 10 of the present disclosure, including any power wires 24 necessary for the operation thereof, may be embedded within the cooling plate 84 using the additive manufacturing method described above and shown in FIG. 2, and the actuator 10 may be operated to vibrate at a predetermined frequency and amplitude to constructively or destructively interfere with an unwanted vibration in the cooling plate 84 to nullify or minimize the unwanted vibration in the same manner as described above with respect to the arm 44 of the manipulator 40. Thus, the stability of the cooling plate 84 and the platen 82 may be improved to mitigate unwanted movement of, and backside damage to, a semiconductor wafer disposed on the platen 82.

Additionally, in various embodiments, a vibration sensor 50 (e.g., an accelerometer) may also be embedded in the cooling plate 84 using the additive manufacturing method described above and shown in FIG. 2, and the vibration sensor 50 may be coupled to a controller 48 by an output wire 52. The vibration sensor 50 may be used to provide a closed loop feedback system (via the controller 48 and the electrical power source 26) for dynamically adjusting the vibration of the actuator 10 to counteract unwanted vibrations in the cooling plate 84 in same manner as described above with respect to the arm 44 of the manipulator 40.

Those of ordinary skill in the art will appreciate the numerous advantages provided by the embodiments of the present disclosure. For example, the various embodiments of the actuator 10 described above may mitigate unwanted vibrations in various components of an ion implanter to improve precision and stability with regard to both wafer handling and beam optics. Moreover, since the actuator 10 is fully embedded and sealed within a component of an ion implanter, the actuator 10 is not subject to ion bombardment thus does not release particulate that could otherwise contaminate a process chamber.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A vibrating actuator adapted to be installed within a component of an ion implanter, the vibrating actuator comprising:
a housing defining an internal cavity; and
a vibrating mechanism disposed within the internal cavity, the vibrating mechanism comprising:
an actuating element; and
a vibratory element coupled to the actuating element;
wherein, when an electrical signal is applied to the actuating element, the actuating element moves the vibratory element to vibrate the housing.

2. The vibrating actuator of claim 1, wherein the actuating element is mounted to a wall of the internal cavity.

3. The vibrating actuator of claim 1, wherein the actuating element is a piezoelectric element and the vibratory element is an elongated strip of material extending through the internal cavity.

4. The vibrating actuator of claim 3, wherein the actuating element is formed of one of stainless steel, aluminum, and a polymer.

5. The vibrating actuator of claim 3, wherein the vibratory element terminates in a weight at a free end thereof.

6. The vibrating actuator of claim 1, wherein the actuating element is a rotary actuator and the vibratory element is an offset weight on a shaft of the rotary actuator.

7. The vibrating actuator of claim 1, wherein the actuating element is a linear actuator and the vibratory element is a cylindrical weight extending through the linear actuator, wherein the linear actuator is adapted to drive the cylindrical weight back and forth in a reciprocating manner.

8. A system for reducing unwanted vibration in a component of an ion implantation system, the system comprising:
a vibrating actuator sealed within the component, the vibrating actuator comprising:
a housing defining an internal cavity;
a vibrating mechanism disposed within the internal cavity, the vibrating mechanism comprising:
an actuating element; and
a vibratory element coupled to the actuating element;
wherein, when an electrical signal is applied to the actuating element, the actuating element moves the vibratory element to vibrate the housing and the component.

9. The system of claim 8, wherein the component is an ion beam manipulator.

10. The system of claim 8, wherein the component is a transfer robot.

11. The system of claim 8, wherein the component is an electrostatic scanner.

12. The system of claim 8, wherein the component is a scan shaft supporting a platen in a process chamber.

13. The system of claim 8, further comprising:
a vibration sensor sealed within the component;
an electrical power source located external to the component; and
a controller located external to the component;
wherein the vibrating actuator, the vibration sensor, and the electrical power source are connected to the controller and wherein the electrical power source is connected to vibrating actuator; and
wherein the vibration sensor measures vibration in the component and transmits a signal communicating the measured vibration to the controller, and wherein, based on the signal received from the vibration sensor, the controller adjusts a frequency of an electrical signal supplied to the vibrating actuator by the electrical power source to tune a frequency and amplitude of vibration produced by the vibrating actuator to mitigate the unwanted vibration in the component.

14. The system of claim 8, wherein the actuating element is a piezoelectric element and the vibratory element is an elongated strip of material extending through the internal cavity.

15. The system of claim 14, wherein the vibratory element terminates in a weight at a free end thereof.

16. The system of claim 8, wherein the actuating element is a rotary actuator and the vibratory element is an offset weight on a shaft of the rotary actuator.

17. The system of claim 8, wherein the actuating element is a linear actuator and the vibratory element is a cylindrical weight extending through the linear actuator, wherein the linear actuator is adapted to drive the cylindrical weight back and forth in a reciprocating manner.

18. A method of embedding a vibrating actuator within a component of an ion implantation system, the method comprising:
starting an additive manufacturing process to build the component, including forming an internal cavity within the component;
pausing the additive manufacturing process while the internal cavity is still open;
installing the vibrating actuator within the internal cavity; and
restarting the additive manufacturing process to cap the internal cavity and seal the vibrating actuator within the internal cavity.

19. The method of claim 18, further comprising filling the internal cavity with a fluid prior to restarting the additive manufacturing process.

20. The method of claim 18, further comprising forming one or more conduits in the component, the one or more conduits extending from the internal cavity to an exterior surface of the component for routing one or more wire to the vibrating actuator.

21. A system for reducing unwanted vibration in a component of an ion implantation system, the system comprising:
a vibrating actuator sealed within the component, the vibrating actuator comprising:
a housing defining an internal cavity; and
a vibrating mechanism disposed within the internal cavity, the vibrating mechanism adapted to vibrate in response to an external vibration to interfere with the external vibration.

22. The system of claim 21, wherein the component is an ion beam manipulator.

23. The system of claim 21, wherein the component is a transfer robot.

24. The system of claim 21, wherein the component is an electrostatic scanner.

25. The system of claim 21, wherein the component is a scan shaft supporting a platen in a process chamber.

26. The system of claim 21, wherein the vibrating mechanism comprises a strip of flexible material coupled to a wall of the internal cavity and terminating in a weight at a free end thereof.

27. The system of claim 21, wherein the vibrating mechanism comprises:
a damper;
an axially movable rod coupled to the damper;
a weight at a free end of the rod opposite the damper; and
a coil spring surrounding the rod and axially held between the weight and the damper.
